(19) United States
(12) Patent Application Publication
(10) Pub. No.: US 2024/0234153 A1
(43) Pub. Date: Jul. 11, 2024

(54) WAFER POLISHING SYSTEM, SIMULATION AND CONTROL METHOD THEREOF

(71) Applicant: SAMSUNG ELECTRONICS CO., LTD., SUWON-SI (KR)

(72) Inventors: Sung Hyup KIM, SUWON-SI (KR); Seok Ryul KIM, SUWON-SI (KR); Se Bin CHOI, SUWON-SI (KR); Jae Hyeon SON, SUWON-SI (KR); Jae-Youn WI, SUWON-SI (KR)

(21) Appl. No.: 18/471,534

(22) Filed: Sep. 21, 2023

(30) Foreign Application Priority Data
Jan. 10, 2023 (KR) 10-2023-0003387

(51) Int. Cl. H01L 21/304; H01L 21/66

(52) U.S. Cl. CPC H01L 21/304; H01L 22/34

(57) ABSTRACT

A wafer polishing method is provided for semiconductor fabrication. The wafer polishing method includes calculating a wear profile of a polishing pad using operation parameters of a pad conditioner, generating a regression model for the wear profile of the polishing pad, and controlling the pad conditioner to condition the polishing pad based on the regression model.

### CROSS-REFERENCE TO RELATED APPLICATION

This application claims priority under 35 U.S.C. § 119 to Korean Patent Application No. 10-2023-0003387, filed on Jan. 10, 2023 in the Korean Intellectual Property Office, the entire disclosure of which is herein incorporated by reference.

### FIELD

The present disclosure relates to a wafer polishing system, simulation and control method for semiconductor fabrication.

### DISCUSSION

In the manufacture of a semiconductor device, chemical mechanical polishing (CMP) is widely used to planarize films formed on a substrate for any height differences therebetween. CMP can efficiently planarize films formed on a substrate, by injecting a slurry containing polishing particles between the substrate and a polishing pad and rubbing the substrate and the polishing pad against each other.

### SUMMARY

Embodiments of the present disclosure may provide a semiconductor wafer polishing system, simulation and control method with high accuracy and reliability.

However, embodiments of the present disclosure are not restricted to those set forth herein. The above and other embodiments of the present disclosure will become more apparent to one of ordinary skill in the art to which the present disclosure pertains by referencing the detailed description of the present disclosure given below.

According to an embodiment of the present disclosure, there is provided a wafer polishing method comprising calculating a wear profile of a polishing pad using operation parameters of a pad conditioner, generating a regression model for the wear profile of the polishing pad, and controlling the pad conditioner to condition the polishing pad based on the regression model.

According to an embodiment of the present disclosure, there is provided a wafer polishing system comprising a memory storing a program, and a processor, wherein the processor executes the program to calculate a wear profile of a polishing pad using a first polishing recipe, to generate a regression model for a wear profile of the polishing pad, to calculate a second polishing recipe using a target wear profile of the polishing pad and the regression model, and to control the polishing pad to polish the wafer based on the second polishing recipe.

According to an embodiment of the present disclosure, there is provided a wafer polishing method comprising calculating a wear profile of a polishing pad using a first polishing recipe, which includes operation parameters of a pad conditioner, and a variation in the polishing pad in accordance with a process weight, generating a regression model for the wear profile of the polishing pad, generating an image visualizing the wear profile of the polishing pad, calculating a second polishing recipe using a target wear profile of the polishing pad and the regression model, and controlling at least one of the pad conditioner or the polishing pad based on at least one of the regression model or the second polishing recipe.

It shall be understood that the features and effects of the present disclosure are not limited to those described above, and that other features and effects of the present disclosure will become apparent from the following description.

### BRIEF DESCRIPTION OF THE DRAWINGS

The above and other embodiments of the present disclosure will become more apparent by describing in detail illustrative embodiments thereof with reference to the attached drawings, in which:

FIG. 1 is a plan view diagram of polishing equipment including a chemical mechanical polishing (CMP) apparatus according to an embodiment of the present disclosure.

FIG. 2 is a perspective view diagram of a CMP apparatus according to an embodiment of the present disclosure.

FIG. 3 is a block diagram of a polishing simulation system according to an embodiment of the present disclosure.

FIG. 4 is a block diagram of a polishing simulation module of FIG. 3.

FIG. 5 is a block diagram of a process results simulation module of FIG. 4.

FIG. 6 is a block diagram illustrating an exemplary operation of the polishing simulation system according to an embodiment of the present disclosure.

FIG. 7 is a block diagram illustrating the exemplary operation of the polishing simulation system according to an embodiment of the present disclosure.

FIG. 8 is a top view diagram illustrating the exemplary operation of the polishing simulation system according to an embodiment of the present disclosure.

FIG. 9 is an enlarged top view diagram of an area a of FIG. 8.

FIG. 10 is a top view diagram illustrating an exemplary operation of the polishing simulation system according to an embodiment of the present disclosure.

FIG. 11 is an enlarged top view diagram of an area b of FIG. 10.

FIG. 12 is an enlarged top view diagram illustrating the operation of the polishing simulation system according to an embodiment of the present disclosure.

FIG. 13 is a graphical diagram for explaining the operation of the polishing simulation system according to an embodiment of the present disclosure.

### DETAILED DESCRIPTION

The inventive concept will be described by way of example with reference to embodiments thereof as illustrated in the attached drawings. Like reference indicia in the various drawings may refer to like features, and duplicate description may be omitted.

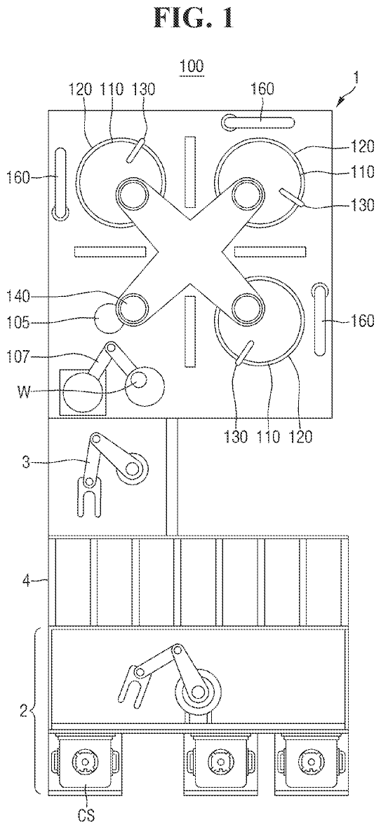

FIG. 1 shows a plan view of polishing equipment 100 including a chemical mechanical polishing (CMP) apparatus according to an embodiment of the present disclosure.

Referring to FIG. 1, the polishing equipment 100 includes a CMP apparatus 1, an index unit 2, a transfer robot 3, and a cleaning apparatus 4.

The CMP apparatus 1 mayperform a polishing process on wafers W. In an embodiment, the CMP apparatus 1 mayinclude polishing pads 110, platens 120, slurry supply units 130, carrier head assemblies 140, and pad conditioners 160.

The index unit 2 mayprovide space in which cassettes CS are placed, having wafers W loaded therein. The index unit 2 maytake wafers W out from each of the cassettes CS to deliver the wafers W to the transfer robot 3, or may put wafers W that have been polished into each of the cassettes CS.

The transfer robot 3 maybe provided between the CMP apparatus 1 and the index unit 2, without limitation thereto. The transfer robot 3 maytransfer wafers W between the CMP apparatus 1 and the index unit 2. For example, a load cup 105 may be disposed in the CMP apparatus 1, adjacent to the transfer robot 3. The load cup 105 may provide space in which wafers W temporarily stand by. An exchanger 107 may be provided between the transfer robot 3 and the load cup 105. The exchanger 107 may deliver a wafer W transferred from the index unit 2 by the transfer robot 3 to the load cup 105 or may deliver a wafer W placed on the load cup 105 to the transfer robot 3.

The cleaning apparatus 4 maybe provided between the index unit 2 and the transfer robot 3, without limitation thereto. A wafer W polished by the CMP apparatus 1 maybe placed on the load cup 105. Then, the polished wafer W may be transferred to the cleaning apparatus 4 by the transfer robot 3, which is disposed adjacent to the load cup 105. The cleaning apparatus 4 mayrinse any contaminants off of the polished wafer W. The wafer W rinsed by the cleaning apparatus 4 maybe transferred to the index unit 2 and may then be accommodated in one of the cassettes CS. In this manner, the polishing of the wafer W may be complete.

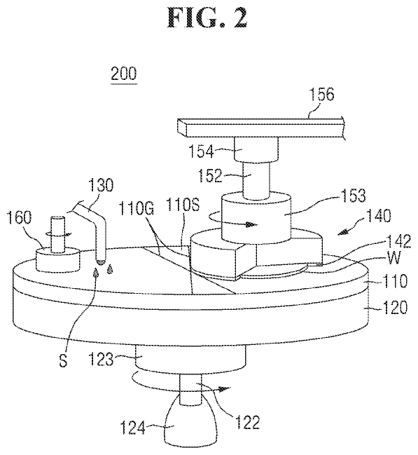

FIG. 2 shows a perspective view of a CMP apparatus 200 according to an embodiment of the present disclosure.

Referring to FIG. 2, the CMP apparatus 200 may include a polishing pad 110, a platen 120, a light irradiation unit 125, a slurry supply unit 130, a carrier head assembly 140, and a pad conditioner 160.

The polishing pad 110 may be disposed on the platen 120. The polishing pad 110 may be provided as a plate, such as but not limited to a circular plate, having a predetermined thickness, but the present disclosure is not limited thereto. The polishing pad 110 may have a polishing surface 110S, which faces a wafer W. The polishing surface 110S may have a predetermined roughness. For example, the polishing surface 110S may be uneven or rugged. During a polishing process, the polishing surface 110S may be in placed in contact with a wafer W to polish the wafer W.

The polishing pad 110 may include a plurality of grooves. The grooves may be formed on the polishing surface 110S of the polishing pad 110. For example, grooves 110G may be formed to be depressed from the polishing surface 110S. During a polishing process, the grooves 110G may serve as passages for a polishing slurry S and may thus facilitate the flow of the polishing slurry S. Although the grooves 110G are illustrated as full straight radii, the present disclosure is not limited thereto. For example, the grooves 110G may be one or more of partial radii, slanted, curved, complex, tiled, mosaic, inlaid, overlaid, or the like.

The platen 120 may support the polishing pad 110. For example, the polishing pad 110 may be disposed on the top surface of the platen 120. The platen 120 may be rotatable. The platen 120 may rotate the polishing pad 110, which is disposed on the platen 120. For example, a first drive shaft 122, which is connected to a lower drive flange 123 of the platen 120, may be rotated by receiving rotational power from a first motor 124. The platen 120 may rotate the polishing pad 110 around a rotational axis substantially perpendicular to the top surface of the platen 120. Although the driveshaft 122 is shown as centered beneath the platen 120, the present disclosure is not limited thereto. For example, the driveshaft 122 may be offset from the center of the platen 120 and/or configured for orbital motion.

The slurry supply unit 130 may be disposed adjacent to the polishing pad 110. During a polishing process, the slurry supply unit 130 may supply the polishing slurry S to the polishing surface 110S of the polishing pad 110. The polishing slurry S may be smoothly supplied between the wafer W and the polishing pad 110 through the grooves 110G on the polishing surface 110S. The slurry supply unit 130 may be positioned above a vertex or inflection point of the grooves 110G.

In an embodiment, the polishing slurry S may include a plurality of polishing particles. For example, the polishing slurry S may include a reactive agent in which polishing particles are dispersed and/or a chemical reaction catalyst. The polishing particles may function as abrasives. The polishing particles may include, for example, at least one of a metal oxide, a metal oxide coated with an organic or inorganic material, and a metal oxide in a colloidal state. For example, the polishing particles may include at least one of silica, alumina, ceria, titania, zirconia, magnesia, germania, and mangania, but the present disclosure is not limited thereto.

The carrier head assembly 140 may be disposed adjacent to the polishing pad 110. The carrier head assembly 140 may provide the wafer W onto the polishing surface 110S of the polishing pad 110. For example, the carrier head assembly 140 may operate to hold the wafer W against the polishing pad 110.

In an embodiment, the carrier head assembly 140 may independently control various polishing parameters, such as but not limited to pressure, for the wafer W. For example, the carrier head assembly 140 may include a retaining ring 142 for retaining the wafer W below a flexible membrane. The carrier head assembly 140 may include a plurality of pressurizable pressure chambers that are defined by the flexible membrane and can be independently controlled. The pressure chambers may apply pressure that can be controlled independently to regions on the flexible membrane and/or on the wafer W.

The carrier head assembly 140 may be rotatable. The carrier head assembly 140 may rotate the wafer W fixed thereon. For example, a second drive shaft 152, which is connected to an upper drive flange 153 of the carrier head assembly 140, may be rotated by receiving rotational power from a second motor 154. Although the second driveshaft 152 is shown as centered above the carrier head assembly 140, the present disclosure is not limited thereto. For example, the second driveshaft 152 may be offset from the center of the carrier head assembly 140 and/or configured for orbital motion.

The carrier head assembly 140 may be supported by a support structure 156. The support structure 156 may be, for example, a carousel or a track, but the present disclosure is not limited thereto. In an embodiment, the carrier head assembly 140 may move laterally across the top surface of the polishing pad 110. For example, the carrier head assembly 140 may vibrate on a slider of the support structure 156 due to the rotational vibration of the support structure 156.

FIG. 2 illustrates that one carrier head assembly 140 is provided on the polishing pad 110, but the present disclosure is not limited thereto. Alternatively, multiple carrier head assemblies 140 may be provided on the polishing pad 110 for an efficient use of the surface area of the polishing pad 110. Also, FIG. 2 illustrates that the platen 120 and the carrier head assembly 140 rotate in the same direction, but the present disclosure is not limited thereto. Alternatively, the platen 120 and the carrier head assembly 140 may rotate in different directions.

The pad conditioner 160 may be disposed adjacent to the polishing pad 110. The pad conditioner 160 may be moveable along a radius of the polishing pad 110. The pad conditioner 160 may perform a conditioning process on the polishing surface 110S of the polishing pad 110. In this manner, the polishing surface 110S of the polishing pad 110 can be stably maintained such that the wafer W can be effectively polished during a polishing process.

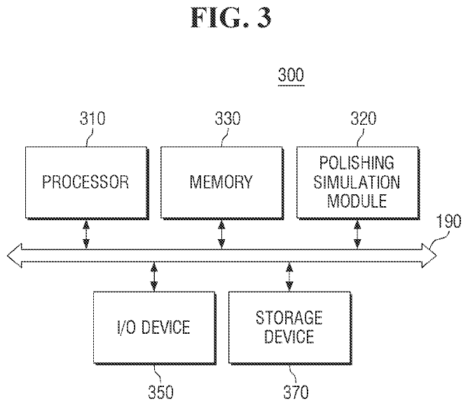

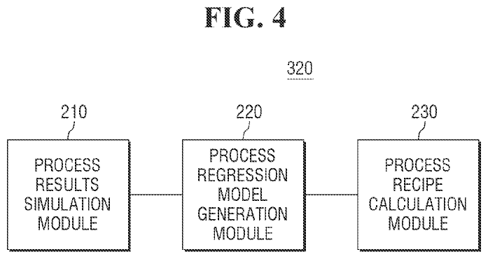

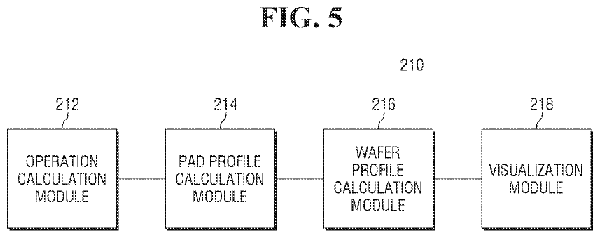

FIG. 3 shows a polishing simulation system 300 according to an embodiment of the present disclosure. FIG. 4 shows a polishing simulation module 320 of FIG. 3. FIG. 5 shows a process results simulation module 210 of FIG. 4.

Referring to FIGS. 2 through 5, a polishing simulation system 300 may include a processor 310, a polishing simulation module 320, a memory 330, an input/output (I/O) device 350, and a storage device 370.

The polishing simulation system 300 may be implemented as, for example, an integrated device. For example, the polishing simulation system 300 may be provided as a dedicated device for polishing simulation. In another example, the polishing simulation system 300 may be a computer for driving various modules for polishing simulation.

The processor 310 may control the polishing simulation system 300. The processor 310 may execute an operating system, firmware, etc. for driving the polishing simulation system 300.

The processor 310 may include a core such as, for example, a microprocessor, an application processor (AP), a digital signal processor (DSP), and a graphics processing unit (GPU), capable of executing arbitrary instructions.

The processor 310 may communicate with the memory 330, the I/O device 350, and the storage device 370 via a bus 190. The processor 310 may simulate polishing using the polishing simulation system 300. For example, the processor 310 may simulate the result of polishing using the polishing simulation module 320 stored in the memory 330. In another example, the processor 310 may calculate a process recipe using the polishing simulation module 320 stored in the memory 330. In another example, the processor 310 may generate a regression model for a polishing profile, using the polishing simulation module 320 stored in the memory 330.

The processor 310 may predict the result of a polishing process by driving the process results simulation module 210 stored in the memory 330. The processor 310 may calculate a wear profile of the polishing pad 110 by driving the process results simulation module 210 stored in the memory 330. The processor 310 may alternately or additionally calculate a wear profile of the wafer W by driving the process results simulation module 210 stored in the memory 330.

The processor 310 may generate a regression model for a polishing process by driving a regression model generation module 220 stored in the memory 330. For example, the processor 310 may calculate a regression model for the wear profile of the polishing pad 110 in accordance with a process recipe, using the regression model generation module 220. The processor 310 may calculate an optimal polishing process recipe for a target wear profile of the polishing pad 110 by driving a process recipe calculation module 230 stored in the memory 330.

The processor 310 may calculate the operation of the pad conditioner 160 by driving an operation calculation module 212 stored in the memory 330. For example, the processor 310 may calculate the operating speed of the pad conditioner 160 and the pressure for the polishing pad 110 by driving the operation calculation module 212.

The processor 310 may calculate the wear profile of the polishing pad 110 by driving a pad profile calculation module 214 stored in the memory 330. For example, the processor 310 may calculate the thickness of the polishing pad 110 after polishing, by driving the pad profile calculation module 214.

The processor 310 may alternately or additionally calculate a wear profile of the wafer W by driving the wafer profile calculation module 216 stored in the memory 330. For example, the processor 310 may calculate the thickness of the wafer W after polishing, by driving the wafer profile calculation module 216.

The processor 310 may visualize the wear profile of the polishing pad 110 by driving a visualization module 218 stored in the memory 330. Also, the processor 310 may visualize the wear profile of the wafer W by driving the visualization module 218 stored in the memory 330. The processor 310 may generate an image corresponding to the wear profile of the polishing pad 110 or the wafer W by driving the visualization module 218 stored in the memory 330.

The polishing simulation module 320 may be a program or software module including multiple instructions that can be executed by the processor 310. The polishing simulation module 320 may be stored in a computer-readable storage medium.

The polishing simulation module 320 may include the process results simulation module 210, the regression model generation module 220, and the process recipe calculation module 230.

The process results simulation module 210 may include the operation calculation module 212, the pad profile calculation module 214, the wafer profile calculation module 216, and the visualization module 218.

The operation calculation module 212 may be a program including instructions for calculating operation parameters of the pad conditioner 160. The pad profile calculation module 214 may be a program including instructions for calculating the wear profile of the polishing pad 110. The wafer profile calculation module 216 may be a program including instructions for calculating the wear profile of the wafer W, without limitation thereto. The visualization module 218 may be a program including instructions for generating an image that visualizes the wear profile of the polishing pad 110 or the wafer W.

The regression model generation module 220 may be a program including instructions for calculating a regression model for the wear profile of the polishing pad 110. The process recipe calculation module 230 may be a program including instructions for calculating a polishing process recipe. For example, the process recipe calculation module 230 may be a program including instructions for calculating a polishing process recipe using the target wear profile of the polishing pad 110.

The memory 330 may temporarily store the polishing simulation module 320. For example, the polishing simulation module 320 may be loaded from the storage device 370 into the memory 330.

The memory 330 may be a volatile memory such as a static random-access memory (SRAM) or a dynamic random-access memory (DRAM) and/or a nonvolatile memory such as a phase-change random-access memory (PRAM), a magnetoresistive random-access memory (MRAM), a resistive random-access memory (ReRAM), a ferroelectric random-access memory (FRAM), or a NOR flash memory, without limitation thereto.

The I/O device 350 may control user input/output to and/or from user interface devices. For example, the I/O device 350 may be equipped with an input device such as a keyboard, a mouse, or a touch pad; and may receive various data. For example, the I/O device 350 may be equipped with an output device such as a display or a speaker and may display or output various types of data.

The storage device 370 may store various data regarding the polishing simulation module 320. The storage device 370 may store an operating system executed by the processor 310 or codes of firmware.

The storage device 370 may include, for example, a memory card such as a MultiMedia Card (MMC), an embedded MMC (eMMC), a Secure Digital (SD) card, or a MicroSD card; a solid-state drive (SSD), or a hard disk drive (HDD), without limitation thereto.

The memory 330 or the storage device 370 may store data used in the polishing simulation module 320. For example, the memory 330 or the storage device 370 may store polishing process weight data provided by the pad profile calculation module 214. The memory 330 or the storage device 370 may store data regarding a chemical reaction that occurs on the polishing pad 110, and/or data regarding the temperature of a polishing process. In another example, the memory 330 or the storage device 370 may store data regarding a polishing process recipe. Moreover, the memory 330 or the storage device 370 may store data regarding a regression model calculated by the regression model generation module 220.

The process results simulation module 210 of the polishing simulation module 320 may calculate the profile of the polishing pad 110 in accordance with a polishing process recipe. The regression model generation module 220 of the polishing simulation module 320 may generate the calculated profile of the polishing pad 110 into a regression model. The process recipe calculation module 230 of the polishing simulation module 320 may calculate the polishing process recipe in accordance with the target wear profile of the polishing pad 110. The process recipe calculation module 230 may use the regression model calculated by the regression model generation module 220 to calculate the polishing process recipe. As the process results simulation module 210 calculates the profile of the polishing pad 110 in accordance with the polishing process recipe and the process recipe calculation module 230 calculates the polishing process recipe in accordance with the target wear profile of the polishing pad 110, the accuracy of the simulation of a polishing process by the polishing simulation system 300 can be optimized. Also, as the process recipe calculation module 230 uses the regression model calculated by the regression model generation module 220, the accuracy of the polishing process recipe calculated by the process results simulation module 210 can also be optimized.

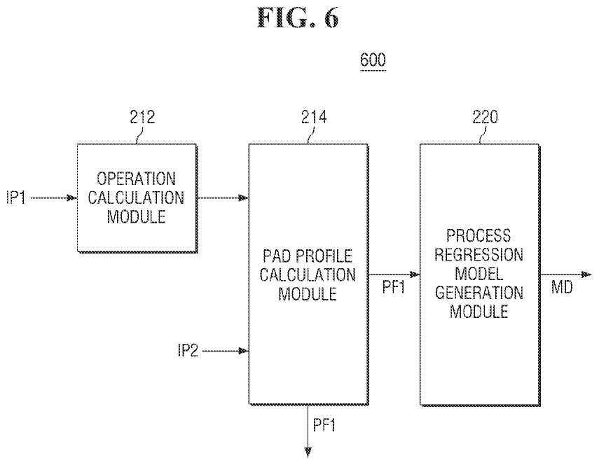

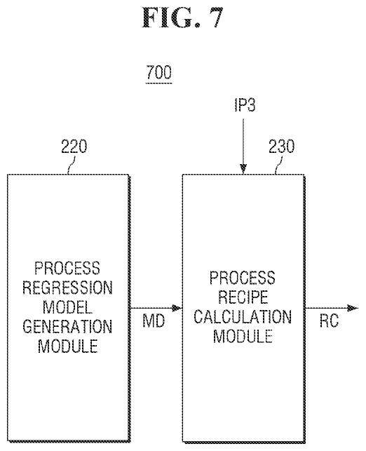

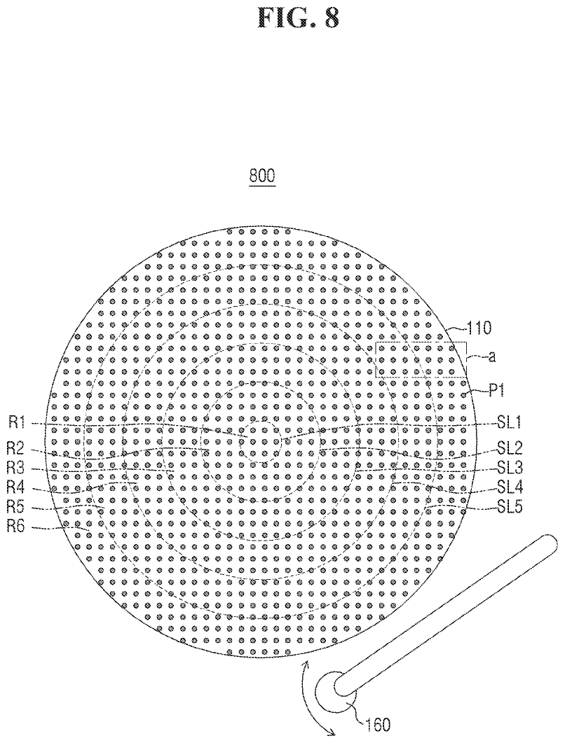

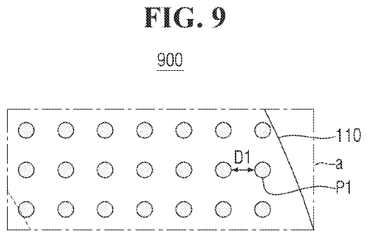

FIG. 6 illustrates an exemplary operation 600 of the polishing simulation system according to an embodiment of the present disclosure. FIG. 7 illustrates an exemplary operation 700 of the polishing simulation system according to an embodiment of the present disclosure. FIG. 8 shows a top view 800 illustrating an exemplary operation of the polishing simulation system according to an embodiment of the present disclosure. FIG. 9 shows an enlarged top view 900 of an area a of FIG. 8.

Referring to FIGS. 6 through 9, the operation calculation module 212 of the process results simulation module 210 may receive first input IP1. The first input IP1 may include a polishing process recipe. The polishing process recipe may include operation parameters of the pad conditioner 160. For example, the polishing process recipe may include the moving speed of the pad conditioner 160. For example, the polishing process recipe may include the residence time of the pad conditioner 160 in each of a plurality of regions on the polishing pad 110.

For example, the polishing pad 110 may include first through sixth regions R1 through R6. The first through sixth regions R1 through R6 may be separated from one another by first through fifth peripheral circles or separation lines SL1 through SL5. The first region R1 may be a region on the inside of the first separation line SL1. The second region R2, in turn, may be a region between the first and second separation lines SL1 and SL2. Similarly, the third region R3 may be a region between the second and third separation lines SL2 and SL3. The fourth region R4, in turn, may be a region between the third and fourth separation lines SL3 and SL4. Similarly, the fifth region R5 may be a region between the fourth and fifth separation lines SL4 and SL5. The sixth region R6 may be a region between the fifth separation line SL5 and a circumferential outer edge of the polishing pad 110.

The first through sixth regions R1 through R6 of the polishing pad 110 may be set in advance. The first through fifth separation lines SL1 through SL5 of the polishing pad 110 may also be set in advance. For example, a user may arbitrarily set the first through sixth regions R1 through R6 and the first through fifth separation lines SL1 through SL5 on the polishing pad 110. The user may set the number of regions into which to divide the polishing pad 110, the number of separation lines to divide the polishing pad 110 into multiple regions, and the size of the multiple regions of the polishing pad 110.

The pad conditioner 160 may be movable on the polishing pad 110. For example, the pad conditioner 160 may be movable on the polishing pad 110 in the form of an arc. The pad conditioner 160 may be movable at different speeds in different regions on the polishing pad 110. For example, the pad conditioner 160 may reside in the first region R1 for a first amount of time, and then may move such as to reside in the second region R2 for a second amount of time, to reside in the third region R3 for a third amount of time, to reside in the fourth region R4 for a fourth amount of time, to reside in the fifth region R5 for a fifth amount of time, and/or to reside in the sixth region R6 for a sixth amount of time, without limitation thereto.

The polishing process recipe may define the residence time of the pad conditioner 160 in each of the first through sixth regions R1 through R6 of the polishing pad 110.

The operation calculation module 212 may calculate operation data of the pad conditioner 160 using the first input IP1. For example, the operation calculation module 212 may calculate the moving speed of the pad conditioner 160 and the pressure against the polishing pad 110 using the first input IP1. The operation calculation module 212 may provide the operation data of the pad conditioner 160, including that calculated by the operation calculation module 212, to the pad profile calculation module 214.

The pad profile calculation module 214 may receive the operation data of the pad conditioner from the operation calculation module 212. Also, the pad profile calculation module 214 may receive second input IP2. The second input IP2 may be provided to the polishing simulation system 300 of FIG. 3. Also, the second input IP2 may be provided from the memory 330 or the storage device 370 of FIG. 3.

The second input IP2 may include polishing process weight data. For example, the polishing process weight data may include chemical reaction data regarding a chemical reaction occurring on the polishing pad 110 and data regarding a variation in the wear of the polishing pad 110 in accordance with the temperature of a polishing process. The chemical reaction data may include information regarding the ingredients of the polishing slurry S of FIG. 2, which is provided to the polishing pad 110.

The pad profile calculation module 214 calculates a first profile PF1 using the operation data of the pad conditioner 160, which is received from the operation calculation module 212, and the second input IP2, which includes the polishing process weight data. The first profile PF1 may include a wear profile of the polishing pad 110. For example, the pad profile calculation module 214 may calculate a wear profile of the polishing pad 110 at each region and/or location.

The polishing pad 110 may include a plurality of first points P1. The first points P1 may be set in advance. The first points P1 may be spaced apart from one another by a first distance D1. The first distance D1 may be arbitrarily set by the user. For example, the first points P1 may be spaced apart from one another by the first distance D1 in an X-axis direction, and spaced apart from one another by substantially the same first distance D1 in a Y-axis direction to form a grid pattern, without limitation thereto.

The pad profile calculation module 214 may calculate a wear profile of the polishing pad 110 at each of the first points P1, without limitation thereto. For example, the pad profile calculation module 214 may calculate the thickness of the polishing pad 110 at each of the first points P1. Alternately, the pad profile calculation module 214 may calculate the thickness of the polishing pad 110 at each of odd-numbered first points in a first iteration, and each of even-numbered first points in a second iteration, without limitation thereto.

The pad profile calculation module 214 may provide the first profile PF1, which includes the wear profile of the polishing pad 110, to the regression model generation module 220 stored in the memory 330 and/or the storage device 370. The pad profile calculation module 214 may output the first profile PF1, which includes the wear profile of the polishing pad 110.

The regression model generation module 220 may generate a regression model MD using the first profile PF1 provided from the pad profile calculation module 214. The regression model MD may include a regression model for the wear profile of the polishing pad 110. For example, the regression model MD may include a regression model for the wear profile of the polishing pad 110 in accordance with the polishing process recipe. For example, the regression model MD may include a regression model for the wear profile of the polishing pad 110 in accordance with the operation parameters of the pad conditioner 160.

The regression model generation module 220 may provide the regression model MD to the process recipe calculation module 230, without limitation thereto.

The process recipe calculation module 230 may receive the regression model MD from the regression model generation module 220. The process recipe calculation module 230 may also receive third input IP3. The third input IP3 may include the target wear profile of the polishing pad 110. The third input IP3 may include the target wear profile of the polishing pad 110 at each of the first points P1. For example, the third input IP3 may include a target thickness of the polishing pad 110 at each of the first points P1.

The process recipe calculation module 230 may calculate a process recipe RC using the regression model MD, which may model the wear profile of the polishing pad 110, and the third input IP3, which may indicate or include the target wear profile of the polishing pad 110. The process recipe calculation module 230 may calculate an optimal polishing process recipe for the polishing pad 110 in accordance with the target wear profile of the polishing pad 110.

The process recipe calculation module 230 may use the regression model MD, generated by the regression model generation module 220, to calculate the optimal polishing process recipe. The process recipe calculation module 230 may repeatedly perform calculation until the difference between the target wear profile of the polishing pad 110, and a wear profile of the polishing pad 110 corresponding to each process recipe input to the regression model MD, becomes substantially equal to or less than a threshold value. The process recipe calculation module 230 may calculate a process recipe that produces a difference substantially equal to or less than the threshold value with the target wear profile of the polishing pad 110 as the optimal polishing recipe.

The process recipe RC calculated by the process recipe calculation module 230 may include the operation parameters of the pad conditioner 160. For example, the process recipe RC may include the moving speed of the pad conditioner 160. For example, the process recipe RC may include the residence time of the pad conditioner 160 in each of the first through sixth regions R1 through R6.

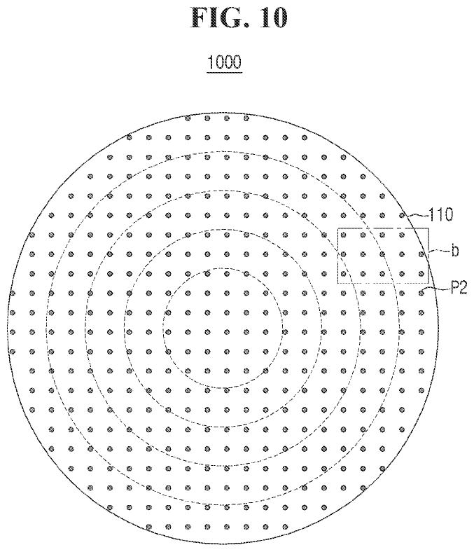

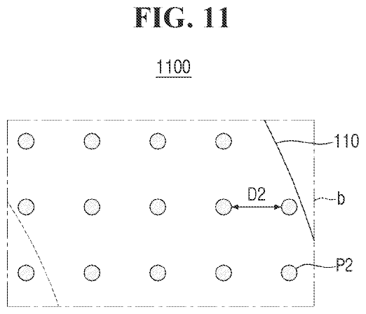

FIG. 10 shows a top view 1000 illustrating an exemplary operation of the polishing simulation system according to an embodiment of the present disclosure. FIG. 11 shows an enlarged top view 1100 of an area b of FIG. 10. The embodiment of FIGS. 10 and 11 will hereinafter be described, focusing mainly on the differences with the embodiment of FIGS. 8 and 9.

Referring to FIGS. 10 and 11, the polishing pad 110 may include a plurality of second points P2. The second points P2 may be spaced apart from one another by a second distance d2.

The pad profile calculation module 214 of FIG. 6 maycalculate a wear profile of the polishing pad 110 at each of the second points P2. The pad profile calculation module 214 may calculate the thickness of the polishing pad 110 at each of the second points P2. The process recipe calculation module 230 of FIG. 7 mayreceive a target wear profile of the polishing pad 110 at each of the second points P2. The process recipe calculation module 230 may receive a target thickness of the polishing pad 110 at each of the second points P2.

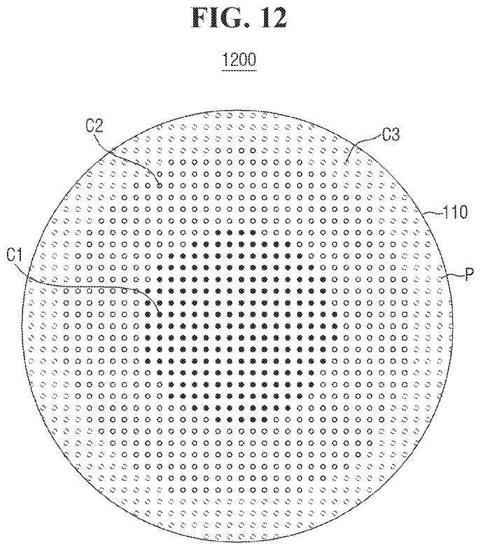

FIG. 12 shows an enlarged top view 1200 illustrating an operation of the polishing simulation system according to an embodiment of the present disclosure.

Referring to FIGS. 5 and 12, the visualization module 218 may visualize a wear profile of the polishing pad 110. For example, the visualization module 218 may generate an image displaying the degrees of wear of the polishing pad 110 at multiple points P of FIG. 12 using different colors.

The visualization module 218 may calculate an image in which some of the points P are displayed in a first color C1, some of the points P are displayed in a second color C2, and some of the points P are displayed in a third color C3, respectively.

The first, second, and third colors C1, C2, and C3 may indicate the degrees of wear at the points P. For example, the first color C1 may correspond to a greater degree of wear than the second and third colors C2 and C3. For example, parts of the polishing pad 110 displayed in the first color C1 may be relatively thin. Moreover, the third color C3 may correspond to a lesser degree of wear than the first and second colors C1 and C2. For example, parts of the polishing pad 110 displayed in the third color C3 may be relatively thick.

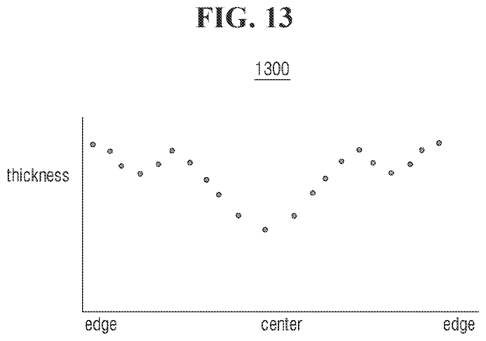

FIG. 13 shows a graph 1300 for explaining the operation of the polishing simulation system according to an embodiment of the present disclosure.

Referring to FIGS. 13 and 5, the pad profile calculation module 214 may calculate a wear profile of the polishing pad 110 of FIG. 2. For example, the pad profile calculation module 214 may calculate the thickness of the polishing pad 110 at each location. For example, the pad profile calculation module 214 may calculate the thickness of the polishing pad 110 at multiple locations ranging from those in the center to those on the edge of the polishing pad 110.

The visualization module 218 may generate an image visualizing the wear profile of the polishing pad 110, as calculated by the pad profile calculation module 214. For example, the visualization module 218 may generate a graph showing the thickness of the polishing pad 110 at each location on the polishing pad 110.

In concluding the detailed description, those of ordinary skill in the pertinent art will appreciate that many variations and modifications may be made to the described embodiments without departing from the principles of the present invention. The present invention has been described by way of example with respect to the illustrated embodiments. Therefore, the described embodiments of the invention are used in a generic and descriptive sense and not for purposes of limitation.

What is claimed is:

1. A wafer polishing method comprising:
calculating a wear profile of a polishing pad using operation parameters of a pad conditioner;
generating a regression model for the wear profile of the polishing pad; and
controlling the pad conditioner to condition the polishing pad based on the regression model.

2. The wafer polishing method of claim 1, further comprising:
generating an image visualizing the wear profile of the polishing pad.

3. The wafer polishing method of claim 2, wherein the image includes a color corresponding to a thickness of the polishing pad at a predefined location on the polishing pad.

4. The wafer polishing method of claim 1, wherein the calculating of the wear profile of the polishing pad comprises calculating a thickness of the polishing pad for at least one predefined location on the polishing pad.

5. The wafer polishing method of claim 1, wherein the calculating of the wear profile of the polishing pad comprises calculating a variation in the wear of the polishing pad in accordance with a process weight.

6. The wafer polishing method of claim 5, wherein the process weight includes information regarding a chemical reaction occurring on the polishing pad and a temperature of a polishing process.

7. The wafer polishing method of claim 1, wherein the operation parameters include a residence time of the pad conditioner in each of a plurality of regions of the polishing pad.

8. The wafer polishing method of claim 1, further comprising:
calculating an optimal polishing recipe using a target wear profile of the polishing pad and the regression model.

9. The wafer polishing method of claim 8, wherein the calculating of the optimal polishing recipe comprises repeatedly performing calculation until a difference between a wear profile corresponding to the optimal polishing recipe obtained using the regression model and the target wear profile becomes substantially equal to or less than a threshold value.

10. The wafer polishing method of claim 1, further comprising:
calculating a wear profile of a wafer to be polished with the polishing pad.

11. A wafer polishing system comprising:
a memory storing a program; and
a processor,
wherein the processor executes the program to calculate a wear profile of a polishing pad using a first polishing recipe, to generate a regression model for a wear profile of the polishing pad, to calculate a second polishing recipe using a target wear profile of the polishing pad and the regression model, and to control the polishing pad to polish the wafer based on the second polishing recipe.

12. The wafer polishing system of claim 11, wherein the memory stores the regression model.

13. The wafer polishing system of claim 11, wherein the first polishing recipe includes operation parameters of a pad conditioner.

14. The wafer polishing system of claim 13, wherein the operation parameters include a residence time of the pad conditioner in each of a plurality of regions of the polishing pad.

15. The wafer polishing system of claim 14, wherein a size of the regions of the polishing pad is set by input from a user.

16. The wafer polishing system of claim 11, wherein the processor receives the first polishing recipe via user input.

17. The wafer polishing system of claim 11, wherein the processor calculates a wear profile of the polishing pad corresponding to the first polishing recipe, using a variation in the wear of the polishing pad in accordance with a process weight.

18. The wafer polishing system of claim 17, wherein the memory stores the process weight.

19. The wafer polishing system of claim 11, wherein the processor executes the program to generate an image visualizing the wear profile of the polishing pad.

20. A wafer polishing method comprising:
calculating a wear profile of a polishing pad using a first polishing recipe, which includes operation parameters of a pad conditioner, and a variation in the polishing pad in accordance with a process weight;
generating a regression model for the wear profile of the polishing pad;
generating an image visualizing the wear profile of the polishing pad;
calculating a second polishing recipe using a target wear profile of the polishing pad and the regression model; and
controlling at least one of the pad conditioner or the polishing pad based on at least one of the regression model or the second polishing recipe.
